(19) United States
(12) Patent Application Publication
(10) Pub. No.: US 2026/0018422 A1
(43) Pub. Date: Jan. 15, 2026

(54) METHOD PROCESSING METAL FEATURES IN A SEMICONDUCTOR SUBSTRATE

(71) Applicant: Tokyo Electron Limited, Tokyo (JP)

(72) Inventor: Yen-Tien Lu, Albany, NY (US)

(21) Appl. No.: 18/771,476

(22) Filed: Jul. 12, 2024

(51) Int. Cl. H01L 21/3213

(52) U.S. Cl. CPC H01L 21/32136

(57) ABSTRACT

A method of processing metal-containing features in a semiconductor substrate where the metal-containing feature comprises a sidewall normal to the major surface plane of the semiconductor substrate, and a top surface having a hard mask cap layer on the top surface is treated by directing an oxidizing gas cluster ion beam (GCIB) at the major surface plane with a first irradiation angle α between the gas cluster ion beam and the major surface plane of from 5° to 85° to selectively oxidize at least a portion of the metal-containing material feature to form an oxidized metal layer. The semiconductor substrate is then treated by dry plasma etching with a reactive ion etching (RIE) process to remove the oxidized metal layer to provide size adapted metal-containing features.

### FIELD

The present invention relates to removing metal-containing materials in small pitch structures, such as integrated circuit structures.

### BACKGROUND

In the semiconductor industry, increasing circuit density drives progress toward smaller and smaller dimensions and larger numbers of transistors placed in an individual device. Metal features in microelectronic devices include contacts and interconnects (i.e., wiring). Metal features in semiconductor devices can be formed by strategies such as damascene techniques and/or metal patterning techniques. In damascene techniques, trenches and vias are formed in a dielectric material, such as by etching, and then the trenches and vias are filled with metal, such as copper or other metal. Patterning techniques involve patterning metal films to form patterned metal features, typically by etching. In contrast to other dielectric materials, metal materials are more challenging to etch; hence, damascene strategies are often used to form metal interconnects. Damascene techniques include dual damascene, single damascene, and semi-damascene strategies. The “single” damascene process involves creating and filling the trenches (or vias) first and then proceeding to fill the trenches (or vias). Then, the etching and filling is repeated for the vias (or trenches). A “Dual” damascene process forms the trenches and vias at the same time and then fills both the trench and vias at the same time.

Gas cluster ion beam (“GCIB”) processes are disclosed in U.S. Pat. No. 11,450,506 that may be used to edit features within a patterned layer to provide feature sizes smaller than the resolution limit of the photolithography system used to form the initial pattern. Additionally, this patent notes that random variations in critical dimensions in a pattern result from surface roughness of sidewalls along the edges of features, such as lines, trenches, pillars, and holes within a patterned layer, and states that GCIB processes can enhance a patterned layer by smoothing the surfaces of features by trimming random protrusions from exposed surfaces using a gas cluster ion beam. Additionally, this patent states that GCIB trim etch process may also be applied to descum a patterned layer. The use of a GCIB to smooth a solid surface of substrate of e.g. a semiconductor is described in US Patent Application Publication Number 2014/0299465. In this disclosure, the angle formed between the solid surface and the gas cluster ion beam is chosen to be between 1° and an angle less than 30°.

A method for removing and/or redistributing material in the trenches and/or vias of integrated circuit interconnect structures by a gas cluster ion beam (GCIB) is described in U.S. Pat. No. 7,115,511 to improve the fabrication process and quality of metal interconnects in an integrated circuit. This patent expressly notes that “The etching/sputtering of the barrier material and/or copper seed material present on the interconnect trench or via sidewall is greatly minimized by the use of a gas cluster ion beam applied at approximately normal incidence to the surface of the integrated circuit (which is approximately parallel to the axis of the cylindrical interconnect via, or in the case of a trench-like via, approximately parallel to the median plane of the trench)” at column 7, lines 12-19.

### SUMMARY

As semiconductor device feature size continues to scale to smaller sizes, it is becoming an increasing challenge to reduce the device contact resistance, especially for devices having very small features using the conventional dual or single damascene flow strategies. Some embodiments of next generation metallization are using semi damascene or subtractive metal etch flow. In a next generation technique, alternative interconnect metals, such as Ru, W, Mo, and Nb with subtractive metal etch techniques are used to form small metal features to replace Cu. These interconnect metals, which have better electric properties and/or advantages of process fabrication compared to Cu as the metal critical dimensions (“CD”) become small, are deposited and then etched to form patterned metal features. In short, subtractive metal etch strategies form small metal features using patterning, and other larger metal features are formed using damascene techniques.

As the dimensions of integrated circuits (“IC”) are reduced and as the component density is increased, significant challenges arise in processing of such features. In particular, chip designs comprising a number of adjacent, very small features having high embodiment ratios may require precise control of critical dimensions.

It has been found that directing an oxidizing gas cluster ion beam (GCIB) at the major surface plane of a substrate at an irradiation angle α between the GCIB and the major surface plane of from 5° to 85° advantageously directs the oxidizing GCIB to locations of the substrate to achieve selective oxidization of at least a portion of the metal-containing material feature to form an oxidized metal layer. Since the oxidizing gas cluster ion beam may be controlled with precision, metal oxidation step can be carried out with high precision relative to the area and depth of the oxidized metal layer.

The semiconductor substrate then undergoes a dry etching with a reactive ion etching (RIE) process to preferentially remove the oxidized metal layer. The sequence of selective oxidization of at least a portion of the metal-containing material feature by a directed oxidizing GCIB to form an oxidized metal layer, followed by the preferential removal of the oxidized metal layer by RIE process to provide metal-containing material features having controlled critical dimensions. In an embodiment, the present process can provide semiconductor substrates comprising metal-containing material features having significantly improved critical dimension control as compared to like semiconductor substrates comprising metal-containing material features that are etched by RIE without previously being selectively oxidized with an oxidizing GCIB.

Removal of metal-containing material by using a highly controllable GCIB process for oxidizing portions of metal-containing features to form an oxidized metal layer, followed by removal of only the oxidized metal layer with a reactive ion etching (RIE) process provides excellent control of the size and/or relative positioning of small dimension metal-containing features. The thus described two-step process affords excellent control of critical dimensions in the resulting size adapted metal-containing features.

### BRIEF DESCRIPTION OF THE DRAWINGS

The accompanying drawings, which are incorporated in and constitute a part of this application, illustrate several embodiments of the invention and together with a description of the embodiments explain the principles of the invention. A brief description of the drawings is as follows:

FIG. 1 is a schematic graphical illustration of a view of a prior art method of processing a recess extending into a semiconductor substrate comprising overhanging metal-containing material.

FIG. 2a is a top view of another schematic graphical illustration of processing a metal-containing a feature in a semiconductor substrate.

FIG. 2b is a cross-sectional view of the process shown in FIG. 2a.

FIG. 3a is a top view of another schematic graphical illustration of processing a metal-containing a feature in a semiconductor substrate.

FIG. 3b is a cross-sectional view of the process shown in FIG. 3a.

FIG. 4 is a schematic graphical illustration of processing a semiconductor wafer comprising multiple metal-containing features.

FIG. 5 is a schematic graphical illustration of a GCIB processing apparatus for directing the gas cluster ion beam onto the major surface plane of a substrate at the desired angle.

FIG. 6 is a schematic graphical illustration of a GCIB processing apparatus for directing the gas cluster ion beam onto the major surface plane of a substrate at the desired angle.

FIG. 7 is a schematic graphical illustration of a view of a method as described herein of processing a semiconductor substrate with a recess extending into the semiconductor substrate.

FIG. 8 is a schematic graphical illustration of a view of a method as described herein of processing a semiconductor substrate with recesses extending into the semiconductor substrate.

FIG. 9 is a schematic graphical perspective illustration of a view of a semiconductor substrate with recesses and extending into the semiconductor substrate being treated by gas cluster ion beam with rotation of the semiconductor substrate.

### DETAILED DESCRIPTION

The embodiments of the present invention described below are not intended to be exhaustive or to limit the invention to the precise forms disclosed in the following detailed description. Rather a purpose of the embodiments chosen and described is by way of illustration or example, so that the appreciation and understanding by others skilled in the art of the general principles and practices of the present invention can be facilitated.

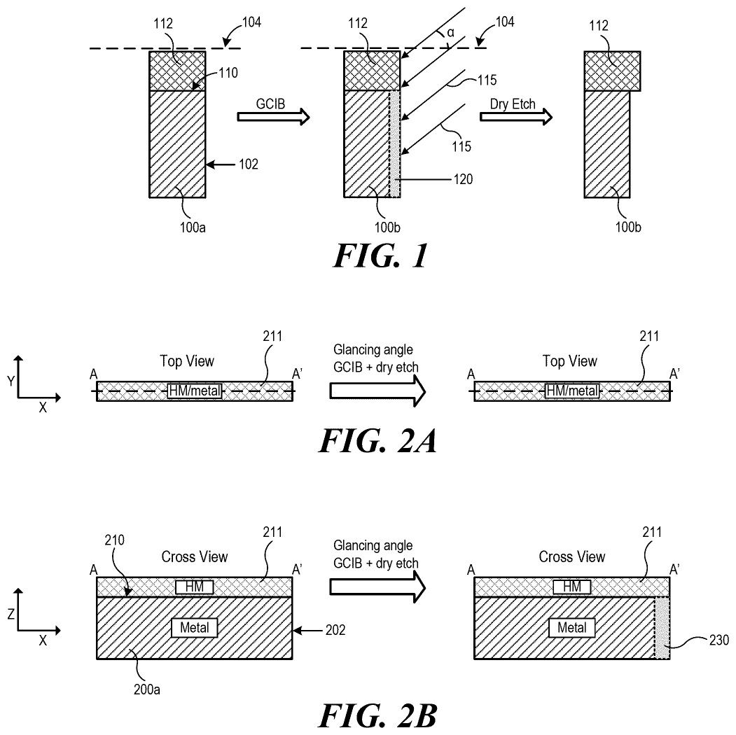

Turning now to the Figures, FIG. 1 is a schematic graphical illustration of a method of processing a metal-containing feature 100a in a semiconductor substrate having a sidewall 102 normal to the major surface plane 104 and a top surface 110 having a hard mask cap layer 112 on the top surface 110. The metal-containing feature 100a may be, for example, a part of a trench, recess, projection, pillar, patterned cell structure, or other configuration benefitting from modification of the feature by controlled reduction of the sidewall. In an embodiment, the line or pillar metal features have a narrowest dimension of not more than 100 nm. In an embodiment, the line or pillar metal features have a narrowest dimension of not more than 50 nm.

The metal-containing feature comprises a metal-containing material selected from Ru, Mo, Nb, W, Ti, TiN, Ta, TaN, Co and Nb.

In an embodiment, the hard mask cap layer 112 comprises a material selected from SiO₂, Si, SiCN, titanium nitride (TiN), titanium oxide (TiO₂), tungsten carbide (WC), WSi, WSIN, tungsten alloys, SiN, SnO₂, organic hard masks, and metal oxide hard masks.

Metal-containing feature 100a is treated in Step 1 by directing an oxidizing gas cluster ion beam (“GCIB”) 115 at the major surface plane 104 with a first irradiation angle α between the gas cluster ion beam and the major surface plane 104 of from 5° to 85° to selectively oxidize at least a portion of the metal-containing material feature to form an oxidized metal layer 120 on the remaining metal-containing feature 100b that is not oxidized. Since the oxidizing gas cluster ion beam may be controlled with precision, metal oxidation step can be carried out with high precision relative to the area and depth of the oxidized metal layer. In an embodiment, the oxidized metal layer has a thickness of no more than 20 nm. In an embodiment, the oxidized metal layer has a thickness of no more than 10 nm. In an embodiment, the oxidized metal layer has a thickness of no more than 5 nm.

Directing the oxidizing gas cluster ion beam at the indicated angle between the gas cluster ion beam and the major surface plane advantageously directs the oxidizing gas cluster ion beam to locations of the metal-containing feature that are conventionally hard to reach, and additionally provides targeted selective oxidization for controlled formation of an oxidized metal layer. Different GCIB conditions may be selected for different directions and locations on the semiconductor substrate to fine tune the metal critical dimensions for some specific regions to improve the critical dimension of the metal.

Ordinarily, the hard mask cap layer 112 is not oxidized by the oxidizing gas cluster ion beam. However, in an embodiment the materials of hard mask cap layer 112 and oxidation conditions of oxidizing GCIB 115 may be selected so that a portion of hard mask cap layer 112 could be oxidized and optionally a portion removed. Conventionally, the hard mask cap layer is instead removed by a separate step in the semiconductor device preparation process.

The GCIB used in the present method comprises oxidizing gases. In an embodiment, the GCIB used in the present method beam comprises an inert gas and an oxidizing gas. In an embodiment, the GCIB used in the present method beam comprises an inert gas selected from nitrogen, helium, neon, argon, krypton, and xenon and an oxidizing gas selected from O₂, CO₂, COS, and SO₂.

In Step 2, the remaining metal-containing feature 100b having the oxidized metal layer 120 thereon is then etched by an RIE process to remove the oxidized metal layer 120, to provide size adapted metal-containing feature 100b having controlled critical dimensions. It has been found that the amount of metal that is etched in this RIE step may be limited to the oxidized metal layer, thereby limiting or eliminating over-etch of the metal sidewall.

The RIE process may be carried out using any appropriate system that preferentially removes oxidized metal layer 120, and does not remove metal-containing feature 100b. In an embodiment, the RIE process uses a reactive gas selected from chlorine (Cl₂), fluorine (F₂), sulfur hexafluoride (SF₆), boron trichloride (BCl₃), HBr, SiCl₄, NF₃, CF₄, CₓF_{y}, and CHₓF_{y}.

It is noted that conventional RIE is sometimes considered to be a directional etch perpendicular to the wafer top surface. However, a significant etch level of lateral etch is actually observed, and is therefore effective in removing materials from sidewall structures that are normal to the major surface plane in the present process.

In an embodiment, the RIE treatment materials may be directed at a single angle or a range of angles to facilitate contact of the ions with the oxidized metal layer 120. Examples of systems for direction of RIE treatment materials may be directed at angles are described, for example, in U.S. Pat. No. 9,118,001. This patent describes techniques of directing ions, for example by use of a sheath modifier configured to modify an electric field within the plasma sheath to control a shape of a boundary between the plasma and the plasma sheath. Accordingly, ions that are attracted from the plasma across the plasma sheath may strike the workpiece at a large range of incident angles. This sheath modifier also may be referred to as, for example, a focusing plate or sheath engineering plate and may be a semiconductor, insulator, or conductor. It is notable that control of direction and intensity of RIE is limited. For this reason, it has been found the treatment of the metal-containing feature with GCIB as described herein first, followed by RIE treatment provides superior definition and precision to remove materials.

Examples of Materials used in this stepwise process are:
1. Ru->GCIB O₂->RuOₓ->Cl-based plasma->RuOₓCl_{y} (volatile)
2. Mo->GCIB O₂->MoOₓ->Cl-based or Br-based plasma->MoOClₓ, MoOBrₓ (volatile)
3. W->GCIB O₂->WOₓ->F-based plasma->WF₆ (volatile)

FIGS. 2a and 2b are another schematic graphical illustration of processing a metal-containing feature 200a in a semiconductor substrate. FIG. 2a is a top view of the process, while FIG. 2b is a cross-sectional view of the same process. As in FIG. 1, a metal-containing feature 200a in a semiconductor substrate having a sidewall 202 normal to the X direction. A hard mask cap layer 211 is provided on the top surface 210. The metal-containing feature 200a may be, for example, a part of a trench, recess, projection, pillar, patterned cell structure, or other configuration benefitting from modification of the feature by controlled reduction of the sidewall.

Metal-containing feature 200a is subjected to sequential treatment by first directing an oxidizing gas cluster ion beam (“GCIB”) using glancing angle techniques as discussed to selectively oxidize at least a portion of the metal-containing material feature to form an oxidized metal layer, followed by dry plasma etched with a reactive ion etching (RIE) process to remove the oxidized metal layer to provide size adapted metal-containing feature 200b having controlled critical dimensions. A portion of metal-containing feature 200a is removed with a high degree of control, and represented by removed portion 230. As shown, the hard mask cap layer 212 is not oxidized by the oxidizing gas cluster ion beam and not removed in the dry plasma etching step.

In an embodiment, the sidewall of metal-containing feature may be controllably reduced in size by removing a sidewall thickness of from about 1 to 20 nm. In an embodiment, the sidewall of metal-containing feature may be controllably reduced in size by removing a sidewall thickness of from about 1 to 10 nm. In an embodiment, the sidewall of metal-containing feature may be controllably reduced in size by removing a sidewall thickness of from about 1 to 5 nm from one side of the metal-containing feature.

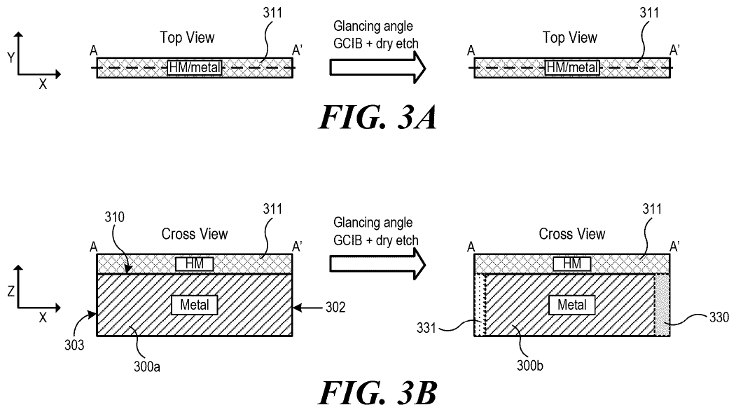

FIGS. 3a and 3b are another schematic graphical illustration of processing a metal-containing feature 300a in a semiconductor substrate. FIG. 3a is a top view of the process, while FIG. 3b is a cross-sectional view of the same process. As in FIG. 2, a metal-containing feature 300a in a semiconductor substrate having a sidewall 302 and also sidewall 303 that are both normal to the X direction. A hard mask cap layer 312 is provided on the top surface 310. The metal-containing feature 300a may be, for example, a part of a trench, recess, projection, pillar, patterned cell structure, or other configuration benefitting from modification of the feature by controlled reduction of the sidewall.

Metal-containing feature 300a is subjected to sequential treatment by first directing an oxidizing gas cluster ion beam (“GCIB”) using glancing angle techniques as discussed to selectively oxidize at least a portion of the metal-containing material feature to form an oxidized metal layer on both sides of the semiconductor substrate, i.e. at sidewall 302 and also at sidewall 303. The oxidizing GCIB treatment is then followed by RIE process to remove the oxidized metal layer to provide size adapted metal-containing feature 300b having controlled critical dimensions. Thus, two portions of metal-containing feature 300a are removed with a high degree of control, and represented by removed portion 330 and removed portion 331. As shown, the hard mask cap layer 312 is not oxidized by the oxidizing GCIB and not removed in the dry plasma etching step.

In an embodiment, the sidewall of metal-containing feature may be controllably reduced in size by removing a sidewall thickness from a plurality of sides of the metal-containing feature, each of the sides having material removed to reduce the sidewall thickness on each side in a thickness amount of from about 1 to 20 nm. In an embodiment, the sidewall of metal-containing feature may be controllably reduced in size by removing a sidewall thickness on each side of from about 1 to 10 nm. In an embodiment, the sidewall of metal-containing feature may be controllably reduced in size by removing a sidewall thickness on each side of from about 1 to 5 nm from one side of the metal-containing feature.

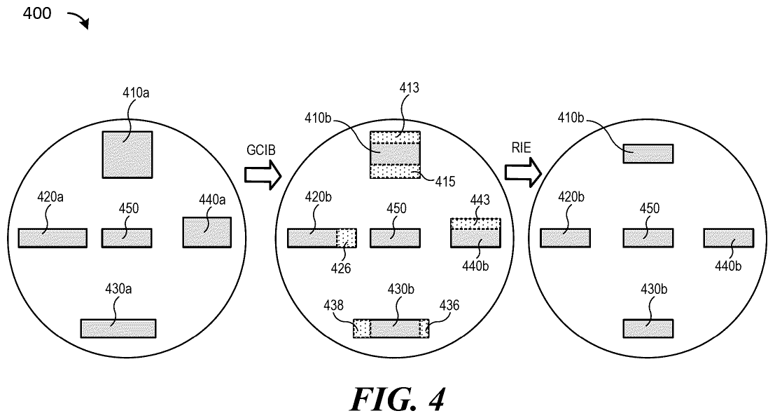

FIG. 4 is a schematic graphical illustration of processing a semiconductor wafer 400 comprising multiple metal-containing features 410a, 420a, 430a, 440a, and 450. Features 410a, 420a, 430a, and 440a are subjected to a first treatment by directing an oxidizing gas cluster ion beam (“GCIB”) using glancing angle techniques as discussed to selectively oxidize at least a portion of each metal-containing material feature to form an oxidized metal layer in the precise location desired for each feature.

In an example of the method, metal-containing feature 410a may be treated by directing an oxidizing GCIB to one side of the feature to form an oxidized metal layer 413 on the remaining size adapted metal-containing feature 410b that is not oxidized. Likewise, metal-containing feature 440a may be treated by directing an oxidizing GCIB to one side of the feature to form an oxidized metal layer 443 on the remaining size adapted metal-containing feature 440b that is not oxidized.

In an embodiment, a plurality of metal-containing line or pillar features are provided on a semiconductor substrate, and the line or pillar features are treated with oxidizing GCIB, followed by RIE to provide size adapted metal-containing features to improve sidewall critical dimension uniformity of the plurality of metal-containing line or pillar features on the semiconductor substrate. In an embodiment, the oxidizing GCIB is directed sequentially at the sidewalls of the plurality of line or pillar features to improve length critical dimension uniformity of the plurality of line or pillar features on the semiconductor substrate. Sequential treatment with the oxidizing GCIB permits tailored adjustment of length of each line or pillar as necessary to achieve the desired length of each line or pillar feature and also the desired length critical dimension uniformity of the plurality of line or pillar features.

The GCIB processing apparatus may then be reconfigured to change the irradiation angle and/or direction as needed to redirect an oxidizing GCIB beam to a different side of one or more features. Redirection of the GCIB beam may, for example, be carried out by one or more of rotating a workpiece holder, adjusting an angle setting mechanism, rotating a workpiece turntable, moving a substrate in an X and/or Y direction relative to the gas cluster ion beam, or moving the GCIB device in an X and/or Y direction relative to the substate as discussed in detail below.

After redirection of the oxidizing GCIB beam, metal-containing feature 420a may be treated by directing an oxidizing GCIB to one side of the feature to form an oxidized metal layer 426 on the remaining size adapted metal-containing feature 420b that is not oxidized. Likewise, metal-containing feature 430a may be treated by directing an oxidizing GCIB to one side of the feature to form an oxidized metal layer 436 on the remaining size adapted metal-containing feature 430b that is not oxidized. The oxidizing GCIB beam may then be redirected again, and the remaining size adapted metal-containing feature 430b may be treated by directing an oxidizing GCIB to the other side of the feature to form an oxidized metal layer 438.

Gas cluster ion beam devices (“GCIB devices”) are known in the art and are described, for example, in U.S. Pat. Nos. 7,115,511; 7,550,748; 9,209,033; 11,450,506; and US Patent Application Publication Number 2014/0299465, the disclosures of which are incorporated by reference herein for purposes of describing components of GCIB devices, configurations of components of GCIB devices and materials used in operation of components of GCIB devices.

In general, a GCIB device may be described as follows: a vacuum vessel is divided into three communicating chambers, a source chamber, an ionization/acceleration chamber, and a processing chamber. The three chambers are evacuated to suitable operating pressures by vacuum pumping systems. A condensable source gas (for example argon or N₂) stored in a gas storage cylinder is admitted under pressure through a gas metering valve and gas feed tube into stagnation chamber and is ejected into the substantially lower pressure vacuum through a properly shaped nozzle, providing a supersonic gas jet. Cooling, which results from the expansion in the jet, causes a portion of the gas jet to condense into clusters, each consisting of from several to several thousand weakly bound atoms or molecules. A gas skimmer aperture partially separates the gas molecules that have not condensed into a cluster jet from the cluster jet so as to minimize pressure in the downstream regions where such higher pressures would be detrimental (e.g., ionizer, high voltage electrodes, and process chamber). Suitable condensable source gases include, but are not necessarily limited to one or more inert gases such as argon and nitrogen, in combination with one or more oxidizing gases such as O₂, CO₂, COS, and SO₂.

After the supersonic gas jet containing gas clusters has been formed, the clusters are ionized in an ionizer. The ionizer is typically an electron impact ionizer that produces thermoelectrons from one or more incandescent filaments and accelerates and directs the electrons causing them to collide with the gas clusters in the gas jet, where the jet passes through the ionizer. The electron impact ejects electrons from the clusters, causing a portion the clusters to become positively ionized. A set of suitably biased high voltage electrodes extracts the cluster ions from the ionizer, forming a beam, then accelerates them to a desired energy (typically from 1 keV to several tens of keV) and focuses them to form a GCIB. Filament power supply provides voltage VF to heat the ionizer filament. Anode power supply provides voltage VA to accelerate thermoelectrons emitted from filament to cause them to irradiate the cluster containing gas jet to produce ions. Extraction power supply provides voltage VE to bias a high voltage electrode to extract ions from the ionizing region of ionizer and to form a GCIB. Accelerator power supply provides voltage VAcc to bias a high voltage electrode with respect to the ionizer so as to result in a total GCIB acceleration energy equal to VAcc electron volts (eV). One or more lens power supplies may be provided to bias high voltage electrodes with potentials to focus the GCIB.

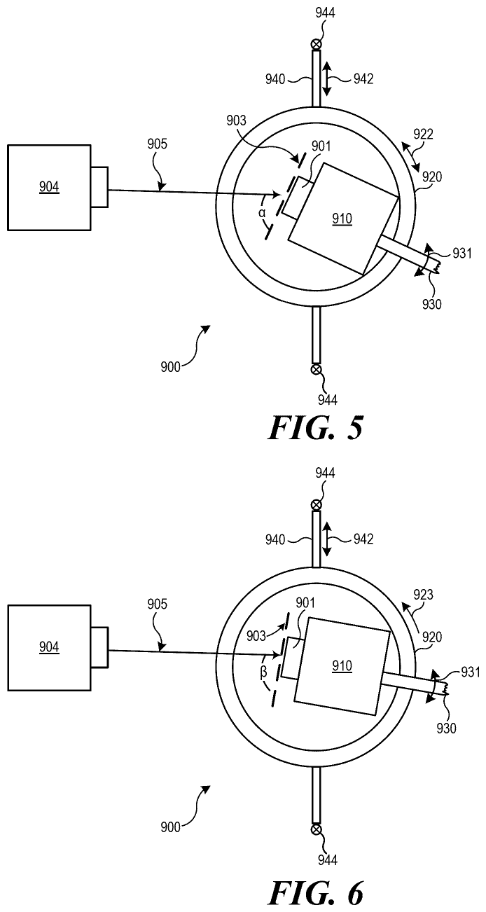

FIG. 5 is a schematic graphical illustration of a gas cluster ion beam processing apparatus 900 for directing the gas cluster ion beam onto the major surface plane of a substrate at the desired angle. A semiconductor substrate 901 having a major surface plane 903 is treated by directing a gas cluster ion beam 905 generated by GCIB device 904 at the major surface plane 903 with a first irradiation angle α between the gas cluster ion beam 905 and the major surface plane 903 of from 5° to 85° to oxidize at least a portion of the undesired metal-containing material. Substrate 901 is held by workpiece holder 910 to maintain the desired irradiation angle for treatment. Workpiece holder 910 is attached to angle setting mechanism 920, which can be rotated as indicated at rotation direction 922 to adjust the irradiation angle as desired to expose the substrate 901 to the gas cluster ion beam 905 from a plurality of angles.

Workpiece holder 910 may additionally be provided with turntable axle 930 that is perpendicular to the major surface plane 903. By rotating turntable axle 930 in rotation direction 931, the substrate is likewise rotated in the plane of major surface plane 903 to expose the substrate 901 to the gas cluster ion beam 905 from a plurality of directions relative to a given point on the substrate 901 without changing first irradiation angle α between the gas cluster ion beam 905 and the major surface plane 903. In an embodiment, workpiece holder 910 (and therefore substrate 901) is rotated stepwise to expose the substrate 901 to the gas cluster ion beam 905 from a plurality of directions relative to a given point on an edge of the substrate 901. In an embodiment, workpiece holder 910 (and therefore substrate 901) is rotated continuously to expose the substrate 901 to the gas cluster ion beam 905 from all directions (i.e., a full 360°) relative to a given point on an edge of the substrate 901.

Workpiece holder 910 and angle setting mechanism 920 may additionally or alternatively be provided with Y-scan actuator 940 that provides linear motion of the workpiece holder 910 in the direction of Y-scan motion 942, X-scan actuator 944 that provides linear motion of the workpiece holder 910 in the direction of X-scan motion (into and out of the plane of the drawing sheet). In an embodiment, the substrate is moved in an X and/or Y direction relative to the gas cluster ion beam to expose a plurality of zones of the substrate to the gas cluster ion beam. In an embodiment, the movement in the X and/or Y direction is a continuous scan movement relative to the gas cluster ion beam.

Alternatively, rather than moving the workpiece holder 910 to treat a plurality of zones of the substrate, the GCIB generator may in an embodiment be moved in the X and/or Y direction relative to the substrate to expose a plurality of zones of the substrate to the gas cluster ion beam.

FIG. 6 is a schematic graphical illustration of a gas cluster ion beam processing apparatus 900 as shown in FIG. 5, wherein angle setting mechanism 920 has been rotated as indicated at rotation direction 923 to adjust the irradiation angle from first irradiation angle α to second irradiation angle β. In an embodiment, the angle setting mechanism 920 is rotated stepwise to expose the substrate 901 to a plurality of irradiation angles ranging from the first irradiation angle α to the second irradiation angle. It has been found that change of the irradiation angle can be instrumental in modifying the depth of sidewall oxidation in the method of processing a recess extending into a semiconductor substrate.

In an embodiment, the angle setting mechanism 920 is rotated continuously to expose the substrate 901 to all irradiation angles ranging from the first irradiation angle α to the second irradiation angle. It has been found that change of the irradiation angle by rotation of the angle setting mechanism can be instrumental to provide continuous control in modifying the depth of sidewall oxidation in the method of processing a recess extending into a semiconductor substrate.

Alternatively, rather than rotating the angle setting mechanism to adjust the irradiation angle between the gas cluster ion beam and the major surface plane, the GCIB generator may in an embodiment be moved relative to the substrate to adjust the irradiation angle between the gas cluster ion beam and the major surface plane.

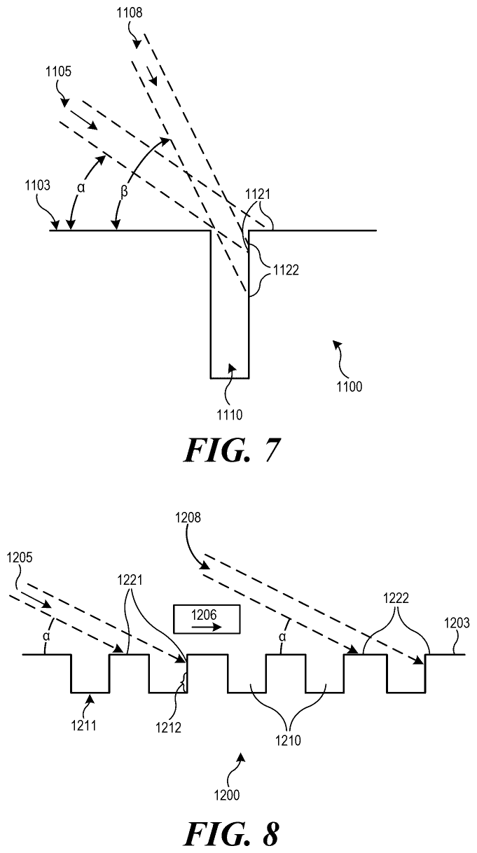

FIG. 7 is a schematic graphical illustration of the step of directing an oxidizing gas cluster ion beam at a semiconductor substrate 1100 with a recess 1110 extending into the semiconductor substrate. A gas cluster ion beam (“GCIB”) 1105 is directed at the major surface plane 1103 with a first irradiation angle α between the GCIB 1105 and the major surface plane 1103. GCIB 1105 contacts semiconductor substrate 1100 in an impact zone 1121. In the method, a GCIB 1108 is directed at the major surface plane 1103 with a second irradiation angle β between the gas cluster ion beam 1108 and the major surface plane 1103. GCIB 1108 contacts semiconductor substrate 1100 in an impact zone 1122. Because of the change in orientation of the GCIB from first irradiation angle α to second irradiation angle β, the different areas on the semiconductor substrate 1100 are selectively treated.

In an embodiment, the GCIB 1108 is generated by a different GCIB device than generated the GCIB 1105. In an embodiment, the GCIB 1108 is generated by the same GCIB device that generated the GCIB 1105, the irradiation angle of the beam being adjusted from the first irradiation angle α to the second irradiation angle β by rotating the angle setting mechanism to adjust the irradiation angle between the gas cluster ion beam and the major surface plane. In an embodiment, the irradiation angle of the beam is adjusted from the first irradiation angle α to the second irradiation angle β by moving the GCIB generator itself relative to the substrate.

In an embodiment, the GCIB does not contact the substrate during the step of adjusting the irradiation angle from the first irradiation angle α to the second irradiation angle β. For example, the GCIB device may be turned off, or the beam may be interrupted by a shutter to block contact of the GCIB with the substrate during movement of the substrate or the GCIB device.

In an embodiment, the GCIB contacts the substrate during the step of adjusting the irradiation angle from the first irradiation angle α to the second irradiation angle β, providing a continuous sweeping exposure of the GCIB to the area on the semiconductor substrate to be selectively treated.

FIG. 8 is a schematic graphical illustration of the step of directing an oxidizing gas cluster ion beam at a semiconductor substrate 1200 with recesses 1210 extending into the semiconductor substrate. A gas cluster ion beam (“GCIB”) 1205 is directed at the major surface plane 1203 with a first irradiation angle α between the GCIB 1205 and the major surface plane 1203. GCIB 1205 contacts semiconductor substrate 1200 in an impact zone 1221. In the method, GCIB 1205 is shifted in direction 1206 to GCIB 1208, still directed at the major surface plane 1203 with a first irradiation angle α between the GCIB 1208 and the major surface plane 1203. The GCIB 1208 contacts semiconductor substrate 1200 in an impact zone 1222. Because of the low irradiation angle α, the GCIB does not impact the bottom 1211 or lower side portions 1212 of recesses 1210.

In an embodiment, the GCIB 1205 is shifted in direction 1206 to GCIB 1208 by moving the substrate in an X and/or Y direction relative to the gas cluster ion beam to expose a portion of or the entire major surface plane of the substrate to the gas cluster ion beam. It should be noted that movement of the semiconductor substrate 1200 in an X and/or Y direction without rotation does not change the irradiation angle of the gas cluster ion beam relative to the major surface plane 1203 of the substrate, but changes the location of the impact zone.

In an embodiment, the movement in the X and/or Y direction is a continuous scan movement.

In an embodiment, the GCIB does not contact the substrate during the step of shifting the GCIB 1205 in direction 1206 to GCIB 1208. For example, the GCIB device may be turned off, or the beam may be interrupted by a shutter to block contact of the GCIB with the substrate during movement of the substrate or the GCIB device.

In an embodiment, the GCIB contacts the substrate during the step of shifting the GCIB 1205 in direction 1206 to GCIB 1208, providing a continuous scanning treatment of the area on the semiconductor substrate to be selectively treated.

In an embodiment, the irradiation angle of the GCIB is adjusted from the first irradiation angle α to a second irradiation angle β between the gas cluster ion beam and the major surface plane of from 5° to 85°, wherein the second irradiation angle β (not shown) is different from the first irradiation angle α), while by moving the substrate in an X and/or Y direction relative to the gas cluster ion beam to expose a portion of or the entire major surface plane of the substrate to the gas cluster ion beam. In an embodiment, the second irradiation angle β between the gas cluster ion beam and the major surface plane is from 5° to 60°. In an embodiment, the second irradiation angle β between the gas cluster ion beam and the major surface plane is from 30° to 60°. The movement of the substrate itself in an X and/or Y direction relative to the gas cluster ion beam in combination with changing the irradiation angle advantageously affords the ability to carry out highly selective surface treatments at different portions of the semiconductor substrate 1200 in a unique and efficient manner. It has been found that moving the substrate in an X and/or Y direction relative to the gas cluster ion beam allows GCIB to provide a different level oxidation and/or application of the GCIB to a different area of the substrate, facilitating a fine tuning of etch in different areas of the substrate.

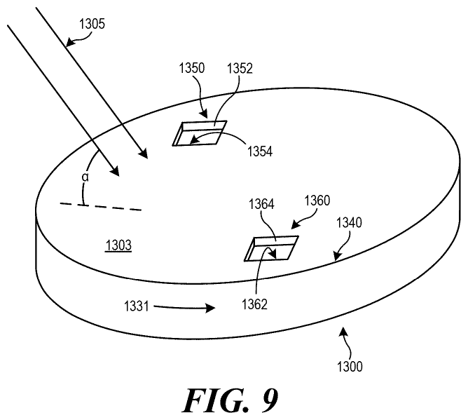

FIG. 9 is a schematic graphical perspective illustration of a view of a semiconductor substrate 1300 with recesses 1350 and 1360 extending into the semiconductor substrate being treated by gas cluster ion beam (“GCIB”) with rotation of the semiconductor substrate 1300. Recess 1350 has an outside wall 1352 proximal to substrate edge 1340, and an inside wall 1354 distal from substrate edge 1340. Likewise, recess 1360 has an outside wall 1362 proximal to substrate edge 1340, and an inside wall 1364 distal from substrate edge 1340. GCIB 1305 is directed at the major surface plane 1303 with a first irradiation angle α between the GCIB 1305 and the major surface plane 1303. Semiconductor substrate 1300 is mounted on a workpiece holder provided with turntable axle that is perpendicular to the major surface plane 1303, such as is illustrated in FIG. 5. Semiconductor substrate 1300 is rotated in the plane of major surface plane 1303 in direction 1331 to expose the substrate 1300 to the gas cluster ion beam 1305 from a plurality of directions relative to a given point on the substrate 1300 without changing first irradiation angle α between the gas cluster ion beam 1305 and the major surface plane 1303. Due to the orientation of semiconductor substrate 1300 to GCIB 1305 as shown in FIG. 9, GCIB contacts inside wall 1354 of recess 1350, but does not contact outside wall 1352. Likewise, GCIB contacts outside wall 1362 of recess 1360, but does not contact inside wall 1364.

Upon rotation of semiconductor substrate 1300 a half turn (i.e. 180 degrees) in the plane of major surface plane 1303 in direction 1331, the previously shaded portions of the recesses are exposed to GCIB 1305. Thus, after rotation GCIB contacts outside wall 1352 of recess 1350, but does not contact inside wall 1354; and GCIB contacts inside wall 1364 of recess 1360, but does not contact outside wall 1362.

In an embodiment, semiconductor substrate 1300 can be treated by stepwise incremental rotation, e.g. in 30 degree, 45 degree, 60 degree, 90 degree increments, with or without GCIB interruption between rotation steps. In an embodiment, semiconductor substrate 1300 can be treated with continuous rotation during GCIB treatment.

In an embodiment, the recesses substrate can be moved in an X and/or Y direction relative to the gas cluster ion beam to treat a plurality of zones of the substrate while rotating semiconductor substrate 1300 in the plane of major surface plane 1303 in direction 1331 to expose the substrate 1300 to the gas cluster ion beam 1305 from a plurality of directions relative to a given point on the substrate 1300. In an alternative embodiment, the GCIB generator that generates a gas cluster ion beam can be moved in the X and/or Y direction relative to the substrate to treat a plurality of zones of the substrate while rotating semiconductor substrate 1300 in the plane of major surface plane 1303 in direction 1331 to expose the substrate 1300 to the gas cluster ion beam 1305 from a plurality of directions relative to a given point on the substrate 1300.

The movement of the substrate itself in an X and/or Y direction relative to the gas cluster ion beam in combination with rotating semiconductor substrate in the plane of major surface plane advantageously affords the ability to carry out highly selective surface treatments at different portions of the semiconductor substrate in a unique and efficient manner.

In an embodiment, the irradiation angle is changed from first irradiation angle α to a second irradiation angle β between the gas cluster ion beam and the major surface plane of from 5° to 85°, wherein the second irradiation angle β is different from the first irradiation angle α, while rotating semiconductor substrate 1300 in the plane of major surface plane 1303 in direction 1331 to expose the substrate 1300 to the gas cluster ion beam 1305 from a plurality of directions relative to a given point on the substrate 1300.

The rotation of the substrate relative to the gas cluster ion beam in combination with changing the irradiation angle advantageously affords the ability to carry out highly selective surface treatments at different portions of the semiconductor substrate in a unique and efficient manner.

In an embodiment, the substrate can be moved in an X and/or Y direction relative to the gas cluster ion beam to treat a plurality of zones of the substrate while the irradiation angle is changed from first irradiation angle α to a second irradiation angle β between the gas cluster ion beam and the major surface plane of from 5° to 85°, wherein the second irradiation angle β is different from the first irradiation angle α, and also while rotating semiconductor substrate 1300 in the plane of major surface plane 1303 in direction 1331 to expose the substrate 1300 to the gas cluster ion beam 1305 from a plurality of directions relative to a given point on the substrate 1300.

In an alternative embodiment, the GCIB generator that generates a gas cluster ion beam can be moved in the X and/or Y direction relative to the substrate to treat a plurality of zones of the substrate while the irradiation angle is changed from first irradiation angle α to a second irradiation angle β between the gas cluster ion beam and the major surface plane of from 5° to 85°, wherein the second irradiation angle β is different from the first irradiation angle α, and also while rotating semiconductor substrate 1300 in the plane of major surface plane 1303 in direction 1331 to expose the substrate 1300 to the gas cluster ion beam 1305 from a plurality of directions relative to a given point on the substrate 1300.

The movement of the substrate itself in an X and/or Y direction relative to the gas cluster ion beam in combination with rotating semiconductor substrate in the plane of major surface plane and also while changing the irradiation angle from first irradiation angle α to a second irradiation angle β advantageously affords the ability to carry out highly selective surface treatments at different portions of the semiconductor substrate in a unique and efficient manner.

In an embodiment, recesses 1350 and 1360 as shown in FIG. 9 are elongated to form a plurality of trench features on a semiconductor substrate, and the trench features are treated with oxidizing GCIB, followed by RIE to provide size adapted metal-containing features to improve sidewall critical dimension uniformity of the plurality of metal-containing line or pillar features on the semiconductor substrate. In an embodiment, the oxidizing GCIB is directed sequentially at the sidewalls of the trench features to improve length critical dimension uniformity of the plurality of line or pillar features on the semiconductor substrate. Sequential treatment with the oxidizing GCIB permits tailored adjustment of length of each trench feature as necessary to achieve the desired length of each trench features and also the desired length critical dimension uniformity of the plurality of trench features.

As used herein, the terms “about” or “approximately” mean within an acceptable range for the particular parameter specified as determined by one of ordinary skill in the art, which will depend in part on how the value is measured or determined, e.g., the limitations of the sample preparation and measurement system. Examples of such limitations include preparing the sample in a wet versus a dry environment, different instruments, variations in sample height, and differing requirements in signal-to-noise ratios. For example, “about” can mean greater or lesser than the value or range of values stated by 1/10 of the stated values, but is not intended to limit any value or range of values to only this broader definition. For instance, a concentration value of 30% means a concentration between 27% and 33%. Each value or range of values preceded by the term “about” is also intended to encompass the embodiment of the stated absolute value or range of values. Alternatively, particularly with respect to biological systems or processes, the term can mean within an order of magnitude, preferably within 5-fold, and more preferably within 2-fold, of a value.

Throughout this specification and claims, unless the context requires otherwise, the word “comprise”, and variations such as “comprises” and “comprising”, will be understood to imply the inclusion of a stated integer or step or group of integers or steps but not the exclusion of any other integer or step or group of integer or step. When used herein “consisting of” excludes any element, step, or ingredient not specified in the claim element. When used herein, “consisting essentially of” does not exclude materials or steps that do not materially affect the basic and novel characteristics of the claim. In the present disclosure of various embodiments, any of the terms “comprising”, “consisting essentially of” and “consisting of” used in the description of an embodiment may be replaced with either of the other two terms.

All patents, patent applications (including provisional applications), and publications cited herein are incorporated by reference as if individually incorporated for all purposes. Unless otherwise indicated, all parts and percentages are by weight and all molecular weights are weight average molecular weights. The foregoing detailed description has been given for clarity of understanding only. No unnecessary limitations are to be understood therefrom. The invention is not limited to the exact details shown and described, for variations obvious to one skilled in the art will be included within the invention defined by the claims.

1. A method of processing metal-containing features in a semiconductor substrate comprising:
providing a semiconductor substrate comprising a major surface plane and having a metal-containing feature comprising a sidewall normal to the major surface plane and a top surface having a hard mask cap layer on the top surface, the metal-containing feature comprising a metal-containing material selected from Ru, Mo, Nb, W, Ti, TiN, Ta, TaN, Co and Nb;
directing an oxidizing gas cluster ion beam at the major surface plane with a first irradiation angle α between the gas cluster ion beam and the major surface plane of from 5° to 85° to selectively oxidize at least a portion of the metal-containing material feature to form an oxidized metal layer,
dry plasma etching the semiconductor substrate with a reactive ion etching (RIE) process to remove the oxidized metal layer to provide size adapted metal-containing features.

2. The method of claim 1, wherein the oxidizing gas cluster ion beam comprises an inert gas and an oxidizing gas selected from O₂, CO₂, COS, and SO₂.

3. The method of claim 1, wherein the reactive ion etching process uses a reactive gas selected from chlorine (Cl₂), fluorine (F₂), sulfur hexafluoride (SF₆), boron trichloride (BCl₃), HBr, SiCl₄, NF₃, CF₄, CₓF_{y}, and CHₓF_{y}.

4. The method of claim 1, wherein the hard mask comprises a material selected from SiO₂, Si, SiCN, titanium nitride (TiN), titanium oxide (TiO₂), tungsten carbide (WC), WSi, WSiN, tungsten alloys, SiN, SnO₂, organic hard masks, and metal oxide hard masks.

5. The method of claim 1, wherein the method is applied to a plurality of metal-containing features on the semiconductor substrate to improve sidewall critical dimension uniformity of the plurality of trench or pillar metal features on the semiconductor substrate.

6. The method of claim 5, wherein the plurality of metal-containing features have a narrowest dimension of not more than 100 nm; or wherein the line or pillar metal features have a narrowest dimension of not more than 50 nm.

7. The method of claim 1, wherein the oxidized metal layer has a thickness of no more than 20 nm; or wherein the oxidized metal layer has a thickness of no more than 10 nm; or wherein the oxidized metal layer has a thickness of no more than 5 nm.

8. The method of claim 1, wherein the method is carried out on a plurality of sides of a metal-containing feature on the semiconductor substrate.

9. The method of claim 1, wherein the first irradiation angle α between the gas cluster ion beam and the major surface plane is selected from the range of from 5° to 60°, or wherein the first irradiation angle α between the gas cluster ion beam and the major surface plane is selected from the range of from 30° to 60°, or wherein the first irradiation angle α between the gas cluster ion beam and the major surface plane is selected from the range of from 5° to 45°, or wherein the first irradiation angle α between the gas cluster ion beam and the major surface plane is selected from the range of from 30° to 45°.

10. The method of claim 1, further comprising a step of adjusting the irradiation angle from first irradiation angle α to a second irradiation angle β between the gas cluster ion beam and the major surface plane of from 5° to 85°, wherein the second irradiation angle β is different from the first irradiation angle α.

11. The method of claim 10, wherein the first irradiation angle α is from 5° to 45° and the second irradiation angle β is from 30° to 85°.

12. The method of claim 1, further comprising a step of moving the semiconductor substrate in an X and/or Y direction relative to the gas cluster ion beam to treat a plurality of zones of the semiconductor substrate; or further comprising a step of moving a GCIB generator that generates a gas cluster ion beam in the X and/or Y direction relative to the substrate to expose a plurality of zones of the semiconductor substrate to the gas cluster ion beam.

13. The method of claim 1, further comprising rotating the semiconductor substrate in the plane of major surface plane to expose the semiconductor substrate to the gas cluster ion beam from a plurality of directions relative to a given point on the semiconductor substrate.

14. (canceled)

15. A method of processing a plurality of metal-containing line or pillar features in a semiconductor substrate comprising:
providing a semiconductor substrate comprising a major surface plane and having a plurality of metal-containing line or pillar features comprising a sidewall normal to the major surface plane and a top surface having a hard mask cap layer on the top surface, the metal-containing feature comprising a metal-containing material selected from Ru, Mo, Nb, W, Ti, TiN, Ta, TaN, Co and Nb;
directing an oxidizing gas cluster ion beam at the major surface plane with a first irradiation angle α between the gas cluster ion beam and the major surface plane of from 5° to 85° to selectively oxidize at least a portion of each of the metal-containing line or pillar features to form an oxidized metal layer,
dry plasma etching the semiconductor substrate with a reactive ion etching (RIE) process to remove the oxidized metal layer on each of the metal-containing line or pillar features to provide size adapted metal-containing features to improve sidewall critical dimension uniformity of the plurality of metal-containing line or pillar features on the semiconductor substrate.

16. The method of claim 15, wherein the line or pillar features have a narrowest dimension of not more than 100 nm; or wherein the line or pillar features have a narrowest dimension of not more than 50 nm.

17. The method of claim 15, wherein the oxidizing gas cluster ion beam is directed sequentially at the sidewalls of the plurality of the line or pillar features to improve length critical dimension uniformity of the plurality of line or pillar features on the semiconductor substrate.

18. A method of processing a plurality of metal-containing trench features in a semiconductor substrate comprising:
providing a semiconductor substrate comprising a major surface plane and having a plurality of trench features comprising a sidewall normal to the major surface plane, the metal-containing feature comprising a metal-containing material selected from Ru, Mo, Nb, W, Ti, TiN, Ta, TaN, Co and Nb;
directing an oxidizing gas cluster ion beam at the major surface plane with a first irradiation angle α between the gas cluster ion beam and the major surface plane of from 5° to 85° to selectively oxidize at least a portion of each of the trench features to form an oxidized metal layer,
dry plasma etching the semiconductor substrate with a reactive ion etching (RIE) process to remove the oxidized metal layer on each of the trench features to provide size adapted metal-containing features to improve sidewall critical dimension uniformity of the plurality trench features on the semiconductor substrate.

19. The method of claim 18, wherein the trench features have a narrowest dimension of not more than 100 nm; or wherein the trench features have a narrowest dimension of not more than 50 nm.

20. The method of claim 18, wherein the oxidizing gas cluster ion beam is directed sequentially at the sidewalls of the plurality of trench features to improve length critical dimension uniformity of the plurality of trench features on the semiconductor substrate.
